(19) United States
(12) Patent Application Publication
(10) Pub. No.: US 2026/0309810 A1
(43) Pub. Date: Oct. 8, 2026

(54) POSITIONALLY-ROBUST CURRENT SENSORS

(71) Applicant: CTS Corporation, Zug (CH)

(72) Inventors: Markus Bartholomäus Roos, Baar (CH); Daniel John Romano, Glattbrugg (CH)

(21) Appl. No.: 19/173,592

(22) Filed: Apr. 8, 2025

(51) Int. Cl. G01R 33/00; G01R 15/20; G01R 19/00

(52) U.S. Cl. CPC G01R 33/0029; G01R 15/207; G01R 19/0092; G01R 33/0005; G01R 33/0035

(57) ABSTRACT

Examples described herein provide current sensors for sensing current flow in a conductor. An example current sensor includes a substrate, a first magnetic field sensing element mechanically connected to the substrate at a first measurement position, and a second magnetic field sensing element mechanically connected to the substrate at a second measurement position. The first magnetic field sensing element and the second magnetic field sensing element measure a magnetic field induced by current flow in the conductor in two non-equivalent measurement positions. The current sensor includes an electronic processor configured to receive a first signal from the first magnetic field sensing element and receive a second signal from the second magnetic field sensing element. The electronic processor is also configured to determine a relative position between the conductor and the substrate and generate an output signal indicative of the current flow in the conductor based on the relative position.

### FIELD

Examples, embodiments, aspects, and features described herein relate to electric current sensors (or, more simply, current sensors).

### BACKGROUND

Magnetic sensors usually include a magnetic field sensing element, for example, a magneto-resistive element, a Hall element, or other element that reacts or interacts with a magnetic field and that generates an output (for example, an electric signal) that is indicative of a magnitude or direction of a magnetic field. Magnetic sensing elements can be used in current sensors to sense or detect current. Current sensors with one or more magnetic field sensing elements commonly use a highly permeable material, known as the core, which forces magnetic flux through an air gap. The magnetic field sensing element or elements detect the magnetic flux in the gap. The core also shields the current sensor from external electro-magnetic interference. Not all current sensors use cores and coreless current sensors have been developed as a cheaper and smaller alternative to current sensors that include a core.

### SUMMARY

Although coreless current sensors exist, they suffer from some deficiencies. Examples, aspects, and features, described herein relate to, among other things, coreless current sensors having a magnetic field sensor arrangement that measures current flowing through a busbar relative to position variations between magnetic field sensing elements and the conductor. In some aspects, current sensors described herein include magnetic field sensing elements mounted on a substrate near a conductor. The magnetic field sensing elements are connected to a signal processing unit, such as an electronic processor, that receives as inputs signals from the magnetic field sensing elements indicative of the sensed magnetic field and outputs a signal indicative of the current flowing in the busbar.

Current sensors described herein may also correct current measurements by estimating relative displacements, such as translations and rotations, between the magnetic field sensing elements and the conductor. For example, the electronic processor may leverage correlations between measurements of components of the busbar's inductive magnetic field probed at different positions.

Some examples described herein provide a current sensor for sensing current flow in a conductor. The current sensor includes a substrate, a first magnetic field sensing element mechanically connected to the substrate at a first measurement position, and a second magnetic field sensing element mechanically connected to the substrate at a second measurement position. The first magnetic field sensing element and the second magnetic field sensing element measure a magnetic field induced by current flow in the conductor in two non-equivalent measurement positions. The current sensor includes an electronic processor connected to the first magnetic field sensing element and the second magnetic field sensing element. The electronic processor is configured to receive a first signal from the first magnetic field sensing element and receive a second signal from the second magnetic field sensing element. The electronic processor is also configured to determine a relative position between the conductor and the substrate based on the first signal, the second signal, and a predicted measurement value or a quantity derived from the predicted measurement value, and generate an output signal indicative of the current flow in the conductor based on the relative position.

Another example described herein provides a method for correcting an output signal of a current sensor. The method includes receiving a first signal from a first magnetic field sensing element and receiving a second signal from a second magnetic field sensing element. The first magnetic field sensing element and the second magnetic field sensing element measure a magnetic field induced by current flow in a conductor in two non-equivalent measurement positions, and the first magnetic field sensing element and the second magnetic field sensing element are each connected to a substrate. The method also includes determining a relative position between the conductor and the substrate based on the first signal, the second signal, and a predicted measurement value or a quantity derived from the predicted measurement value, and generating an output signal indicative of the current flow in the conductor based on the relative position.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate examples, instances, and/or aspects of concepts that include the claimed subject matter, and explain various principles and advantages of examples, instances, and/or aspects.

FIG. 1 is a cross-sectional view of an example coreless current sensor according to some aspects.

FIG. 2 is a cross-sectional view of another example coreless current sensor 200 according to some aspects.

FIG. 3 is a block diagram of the current sensor of FIG. 2 according to some aspects.

FIG. 4 is a cross-sectional view of another example coreless current sensor according to some aspects.

FIG. 5 is a cross-sectional view of another example coreless current sensor according to some aspects.

FIG. 6 is a cross-sectional view of another example coreless current sensor according to some aspects.

FIG. 7 is a cross-sectional view of another example coreless current sensor according to some aspects.

FIG. 8 is a cross-sectional view of another example coreless current sensor according to some aspects.

FIG. 9 is a block diagram of a method for calibrating coreless current sensors according to some aspects.

FIG. 10 is a block diagram of a method for operating a coreless current sensor according to some aspects.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of examples.

The apparatus and method components have been represented where appropriate by conventional symbols in the drawings, showing only those specific details that are pertinent to understanding the examples, instances, and aspects illustrated so as not to obscure the disclosure with details that will be readily apparent to those of ordinary skill in the art having the benefit of the description herein.

### DETAILED DESCRIPTION

One or more aspects are described and illustrated in the following description and accompanying drawings. These aspects are not limited to the specific details provided herein and may be modified in various ways. Furthermore, other aspects may exist that are not described herein. For example, a device or structure that is “configured” in a certain way is configured in at least that way but may also be configured in ways that are not listed. Furthermore, some aspects described herein may include one or more electronic processors configured to perform the described functionality by executing instructions stored in non-transitory, computer-readable medium. Similarly, aspects described herein may be implemented as non-transitory, computer-readable medium storing instructions executable by one or more electronic processors to perform the described functionality. As used in the present application, “non-transitory computer-readable medium” comprises all computer-readable media but does not include a transitory, propagating signal. Accordingly, non-transitory computer-readable medium may include, for example, a hard disk, a CD-ROM, an optical storage device, a magnetic storage device, ROM (Read Only Memory), RAM (Random Access Memory), register memory, a processor cache, other memory and storage devices, or combinations thereof.

In addition, the phraseology and terminology used herein is for the purpose of description and should not be regarded as limiting. For example, the use of “including,” “containing,” “comprising,” “having,” and variations thereof herein is meant to encompass the items listed thereafter and equivalents thereof as well as additional items. The terms “connected” and “coupled” are used broadly and encompass both direct and indirect connecting and coupling. Further, “connected” and “coupled” are not restricted to physical or mechanical connections or couplings and can include electrical connections or couplings, whether direct or indirect. In addition, electronic communications and notifications may be performed using wired connections, wireless connections, or a combination thereof and may be transmitted directly or through one or more intermediary devices over various types of networks, communication channels, and connections. Moreover, relational terms, for example, first and second, top and bottom, and the like may be used herein solely to distinguish one entity or action from another entity or action without necessarily requiring or implying any actual such relationship or order between such entities or actions.

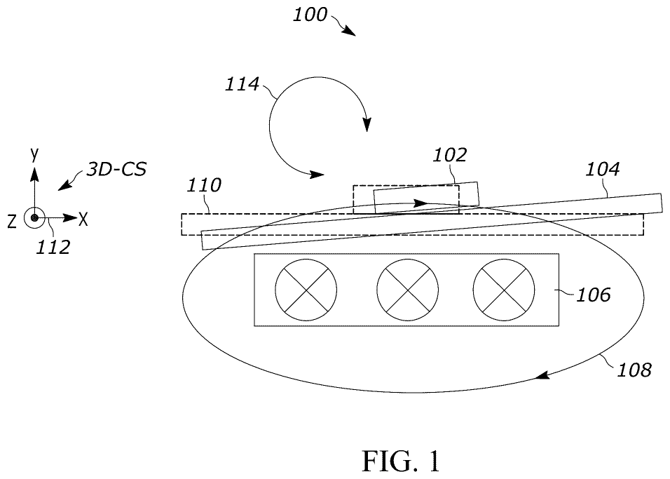

Coreless current sensors may experience movement from the position at which they were calibrated, increasing error in the signal output by the current sensor. FIG. 1 is a cross-sectional view of an example coreless current sensor 100. In the example shown, the current sensor 100 includes a magnetic field sensing element 102 situated on a substrate 104 (for example, a printed circuit board). The magnetic field sensing element 102 and the substrate 104 are adjacent to (for example, located above) a conductor 106. When current flows through the conductor 106, a magnetic field 108 is induced (e.g., generated or created). At least a portion of the magnetic field 108 is sensed by the magnetic field sensing element 102.

In the example of FIG. 1, the magnetic field sensing element 102 and the substrate 104 have shifted away from an initial calibration position 110 (shown in FIG. 1 as a dotted line). The accuracy and performance of the current sensor 100 is dependent on the magnetic field sensing element 102 and the substrate 104 remaining at the calibration position 110. However, during operation, the magnetic field sensing element 102 and the substrate 104 may experience rigid body translation and move along a translation axis 112 (for example, along the x, y or z axis of the three-dimensional coordinate system 3D-CS) or along a rotational axis 114 due to, for example, mechanical vibrations or changes in temperature (which may cause mechanical components near the current sensor 100 to expand).

Examples described herein provide, among other things, coreless current sensors that are positionally robust. In some instances, a coreless current sensor with multiple magnetic field sensing elements is provided. In some instances, an electronic processor applies a correction based on changes in signals from one or more of the magnetic field sensing elements to estimate the current flowing through the busbar after the current sensor shifts from the position at which it was calibrated. Magnetic field sensing elements described herein may refer to a sensing element configured to sense a single component of a magnetic field. Magnetic field sensors described herein may refer to a sensor including two or more magnetic field sensing elements. The magnetic field sensing elements included in a magnetic field sensor may be configured to sense different components of a magnetic field.

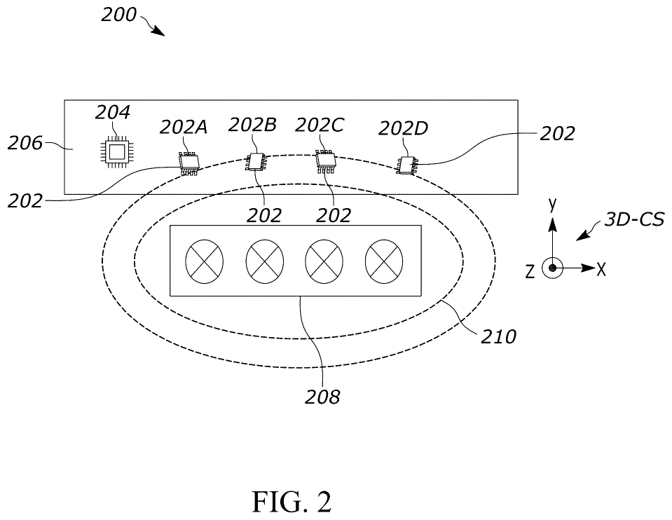

FIG. 2 is a cross-sectional view of another example coreless current sensor 200. In the example shown, the current sensor 200 includes a plurality of magnetic field sensing elements 202 and a controller 204 (for example, a microcontroller) situated on (for example, mechanically connected to) a substrate 206 (for example, a printed circuit board). The plurality of magnetic field sensing elements 202 may each be in a same plane defined by the substrate 206. In some implementations, the substrate 206 includes components on both surface (e.g., a bottom surface and a top surface). In such an implementation, both surfaces of the substrate 206 are considered to be the same plane. The substrate 206 is situated adjacent to a conductor 208. When current flows through the conductor 208, a magnetic field 210 is induced. At least a portion of the magnetic field 210 is sensed by the plurality of magnetic field sensing elements 202.

In some instances, the plurality of magnetic field sensing elements 202 are configured to measure a particular component of the magnetic field 210. For example, the plurality of magnetic field sensing elements 202 may include a first magnetic field sensing element 202A, a second magnetic field sensing element 202B, a third magnetic field sensing element 202C, and a fourth magnetic field sensing element 202D. The first magnetic field sensing element 202A and the third magnetic field sensing element 202C may be configured to sense the x-component of the magnetic field 210 (e.g., the magnitude of the magnetic field 210 in the x-direction of a three-dimensional coordinate system 3D-CS that includes x, y, and z axes). The second magnetic field sensing element 202B and the fourth magnetic field sensing element 202D may be configured to sense the y-component of the magnetic field 210 (e.g., the magnitude of the magnetic field 210 in the y-direction). In some instances, the plurality of magnetic field sensing elements 202 each sense one or two components in the plane defined by the substrate 206 comprising the plurality of magnetic field sensing elements 202. Additionally, the plurality of magnetic field sensing elements 202 may be configured or situated (for example, situated asymmetrically along the substrate 206) such that each of the plurality of magnetic field sensing elements 202 provide non-equivalent measurement information, as described below in more detail.

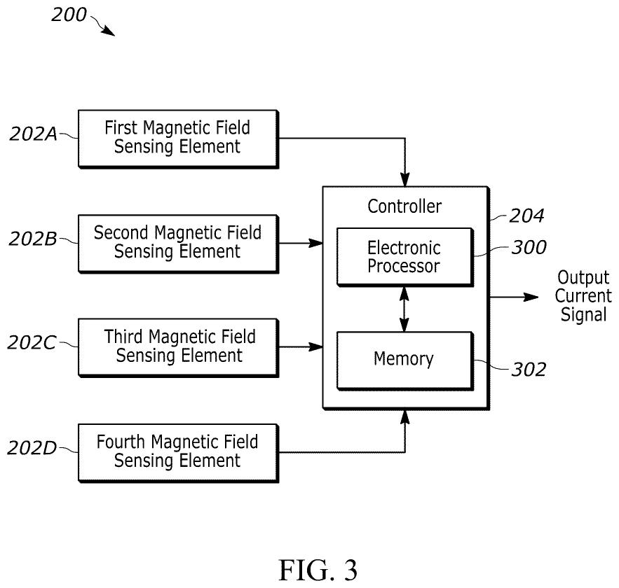

FIG. 3 is a block diagram of the current sensor 200. In the example illustrated in FIG. 3, the current sensor 200 includes the first magnetic field sensing element 202A, the second magnetic field sensing element 202B, the third magnetic field sensing element 202C, the fourth magnetic field sensing element 202D, and the controller 204. The controller 204 includes an electronic processor 300 (for example, a programmable microprocessor, a microcontroller, a programmable logic controller, or other suitable device) and a memory 302. The controller 204 may provide an output current signal indicative of a current value estimated by the current sensor 200 and flowing through the conductor 208 (shown in FIG. 2).

The memory 302 is a non-transitory computer readable medium that includes, for example, a program storage area and a data storage area. The program storage area and the data storage area can include combinations of different types of memory, for example read-only memory (“ROM”), random access memory (“RAM”) (for example, dynamic RAM [“DRAM”], synchronous DRAM [“SDRAM”], etc.), electrically erasable programmable read-only memory (“EEPROM”), flash memory, a hard disk, an SD card, or other suitable magnetic, optical, physical, or electronic memory devices. In one example, the electronic processor 300 is connected to the memory 302 and executes software instructions that are capable of being stored in a RAM of the memory 302 (for example, during execution), a ROM of the memory 302 (for example, on a generally permanent basis), or another non-transitory computer-readable medium. Software included in the implementation of the current sensor 200 can be stored in the memory 302. The software includes, for example, firmware, one or more applications, program data, filters, rules, one or more program modules, or other executable instructions. The electronic processor 300 is configured to retrieve from the memory 302 and execute, among other things, instructions related to the control processes and methods described herein. In other constructions, the sensor 200 includes additional, fewer, or different components. For example, while illustrated as including four magnetic field sensing elements 202, the sensor 200 may alternatively include additional or fewer magnetic field sensing elements 202.

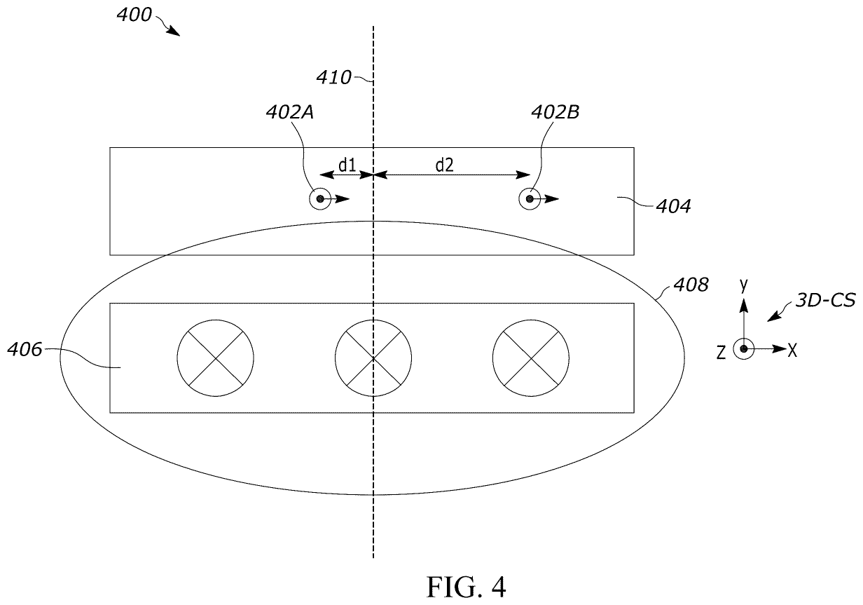

FIG. 4 is a cross-sectional view of another example coreless current sensor 400. The current sensor 400 includes a first magnetic field sensing element 402A and a second magnetic field sensing element 402B situated on a substrate 404 (for example, a printed circuit board). The substrate 404 is situated adjacent to a conductor 406. The substrate 404 may be a printed circuit board (PCB), a silicon substrate, a ceramic substrate, a lead frame, or the like. When current flows through the conductor 406, a magnetic field 408 is induced. At least a portion of the magnetic field 408 is sensed by the first magnetic field sensing element 402A and the second magnetic field sensing element 402B. While not illustrated, the current sensor 400 may also include a controller situated on the substrate 404.

In the example of FIG. 4, an axis of symmetry 410 intercepts a center of the substrate 404 and a center of the conductor 406. The first magnetic field sensing element 402A and the second magnetic field sensing element 402B are situated asymmetrically on the substrate 404 with respect to the axis of symmetry 410. For example, the first magnetic field sensing element 402A is separated from the axis of symmetry 410 by a first distance d1 and in a first direction. The second magnetic field sensing element 402B is separated from the axis of symmetry 410 by a second distance d2 in a second direction opposite the first direction. For example, the second direction is a different axial direction from the first direction. As the first magnetic field sensing element 402A and the second magnetic field sensing element 402B are different distances from the axis of symmetry 410, the first magnetic field sensing element 402A and the second magnetic field sensing element 402B are also located at different radial distances from the conductor 406. The first magnetic field sensing element 402A and the second magnetic field sensing element 402B may be configured to sense the same component of the magnetic field 408 (for example, the x-component).

As the first magnetic field sensing element 402A and the second magnetic field sensing element 402B are on opposite sides of the axis of symmetry 410, and as the second magnetic field sensing element 402B is a further distance from the axis of symmetry 410 than the first magnetic field sensing element 402A, the first magnetic field sensing element 402A and the second magnetic field sensing element 402B sense non-equivalent values of the magnetic field 408. By way of example, in FIG. 4, the first magnetic field sensing element 402A is positioned closer to the axis of symmetry 410 than the second magnetic field sensing element 402B. The first magnetic field sensing element 402A senses a greater magnitude of the magnetic field 408 than the second magnetic field sensing element 402B, and, accordingly, the first magnetic field sensing element 402A senses a non-equivalent value of the magnetic field 408 when compared to the second magnetic field sensing element 402B.

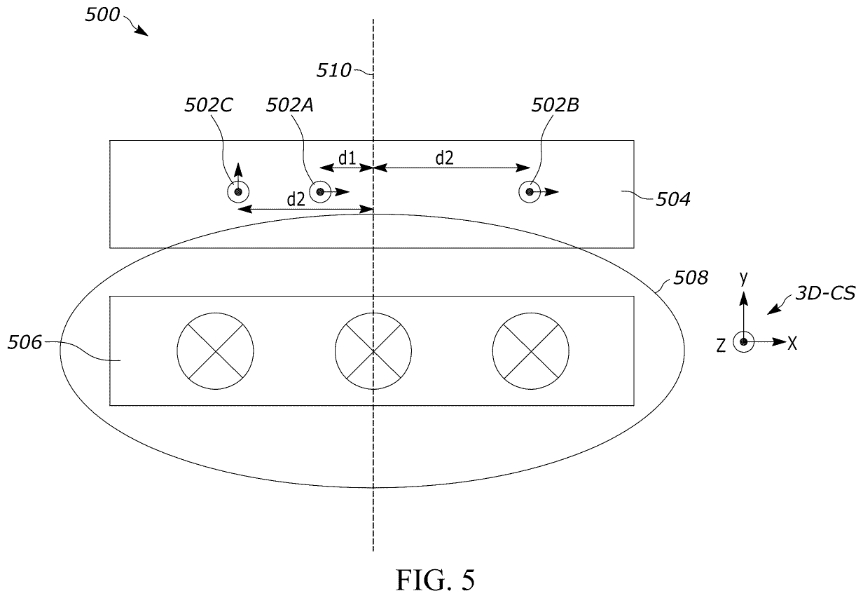

FIG. 5 is a cross-sectional view of another example coreless current sensor 500. The current sensor 500 includes a first magnetic field sensing element 502A, a second magnetic field sensing element 502B, and a third magnetic field sensing element 502C situated on a substrate 504 (for example, a printed circuit board). The substrate 504 is situated adjacent to a conductor 506. When current flows through the conductor 506, a magnetic field 508 is induced. At least a portion of the magnetic field 508 is sensed by the first magnetic field sensing element 502A, the second magnetic field sensing element 502B, and the third magnetic field sensing element 502C. While not illustrated, the current sensor 500 may also include a controller situated on the substrate 504.

In the example of FIG. 5, an axis of symmetry 510 intercepts a center of the substrate 504 and a center of the conductor 506. The first magnetic field sensing element 502A is situated asymmetrically on the substrate 504 with respect to the second magnetic field sensing element 502B and the third magnetic field sensing element 502C. For example, the first magnetic field sensing element 502A is separated from the axis of symmetry 510 by a first distance d1 in a first direction. The second magnetic field sensing element 502B is separated from the axis of symmetry 510 by a second distance d2 in a second direction opposite the first direction. The third magnetic field sensing element 502C is separated from the axis of symmetry 510 by the second distance d2 in the first direction opposite the second direction. Accordingly, in the example of FIG. 5, the third magnetic field sensing element 502C and the second magnetic field sensing element 502B are symmetrically spaced with respect to the axis of symmetry 510. In other examples, however, the second magnetic field sensing element 502B and the third magnetic field sensing element 502C may be asymmetrically spaced with respect to the axis of symmetry 510.

The first magnetic field sensing element 502A and the second magnetic field sensing element 502B may be configured to sense the same component of the magnetic field 508 (for example, the x-component). The third magnetic field sensing element 502C may be configured to sense a different component of the magnetic field 508 compared to the first magnetic field sensing element 502A and the second magnetic field sensing element 502B (for example, the y-component).

As the first magnetic field sensing element 502A and the second magnetic field sensing element 502B are on opposite sides of the axis of symmetry 510, and as the second magnetic field sensing element 502B is a further distance from the axis of symmetry 510 than the first magnetic field sensing element 502A, the first magnetic field sensing element 502A and the second magnetic field sensing element 502B sense non-equivalent values of the magnetic field 508. By way of example, in FIG. 5, the first magnetic field sensing element 502A is positioned closer to the axis of symmetry 510 than the second magnetic field sensing element 502B. The first magnetic field sensing element 502A senses a greater magnitude of the magnetic field 508 than the second magnetic field sensing element 502B, and, accordingly, the first magnetic field sensing element 502A senses a non-equivalent value of the magnetic field 508 when compared to the second magnetic field sensing element 502B.

Additionally, while the third magnetic field sensing element 502C is the same distance d2 from the axis of symmetry 510 as the second magnetic field sensing element 502B, the third magnetic field sensing element 502C senses a different component of the magnetic field 508 than the second magnetic field sensing element 502B. As the second magnetic field sensing element 502B and the third magnetic field sensing element 502C sense different components of the magnetic field 508, the second magnetic field sensing element 502B and the third magnetic field sensing element 502C sense non-equivalent values of the magnetic field 508.

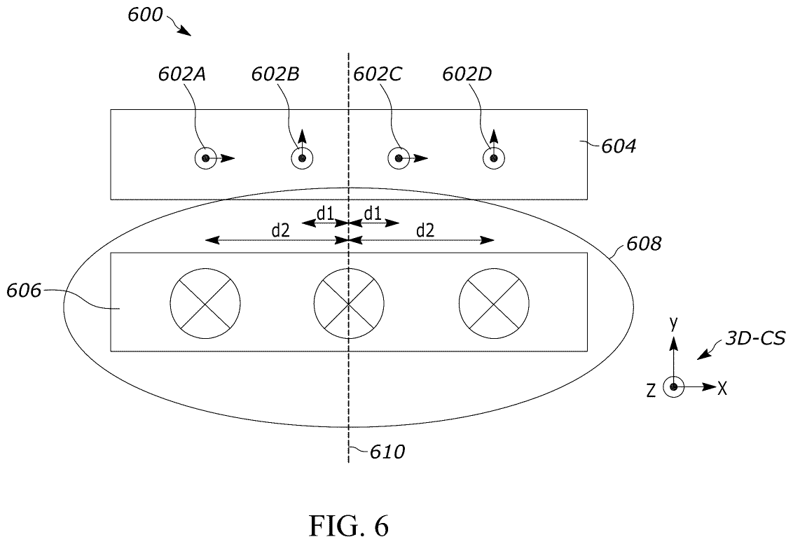

FIG. 6 is a cross-sectional view of another example coreless current sensor 600. The current sensor 600 includes a first magnetic field sensing element 602A, a second magnetic field sensing element 602B, a third magnetic field sensing element 602C, and a fourth magnetic field sensing element 602D on a substrate 604 (for example, a printed circuit board). The substrate 604 is situated adjacent to a conductor 606. When current flows through the conductor 606, a magnetic field 608 is induced. At least a portion of the magnetic field 608 is sensed by the first magnetic field sensing element 602A, the second magnetic field sensing element 602B, the third magnetic field sensing element 602C, and the fourth magnetic field sensing element 602D. While not illustrated, the current sensor 600 may also include a controller situated on the substrate 604.

In the example of FIG. 6, an axis of symmetry 610 intercepts a center of the substrate 604 and a center of the conductor 606. In the example of FIG. 6, the first magnetic field sensing element 602A and the fourth magnetic field sensing element 602D are symmetrically spaced with respect to the axis of symmetry 610. Additionally, the second magnetic field sensing element 602B and the third magnetic field sensing element 602C are symmetrically spaced with respect to the axis of symmetry 610. In other examples, each of the first magnetic field sensing element 602A the second magnetic field sensing element 602B the third magnetic field sensing element 602C and the fourth magnetic field sensing element 602D may be asymmetrically spaced with respect to the axis of symmetry 610.

The first magnetic field sensing element 602A is situated asymmetrically on the substrate 604 with respect to the third magnetic field sensing element 602C. For example, the first magnetic field sensing element 602A is separated from the axis of symmetry 610 by a second distance d2 in a first direction. The third magnetic field sensing element 602C is separated from the axis of symmetry 610 by a first distance d1 in a second direction. The first magnetic field sensing element 602A and the third magnetic field sensing element 602C may be configured to sense the same component of the magnetic field 608 (for example, the x-component). However, while the first magnetic field sensing element 602A and the third magnetic field sensing element 602C sense the same component of the magnetic field 608, as the first magnetic field sensing element 602A and the third magnetic field sensing element 602C are separated from the symmetry 610 by different distances, the first magnetic field sensing element 602A and the third magnetic field sensing element 602C sense non-equivalent values of the magnetic field 608.

The second magnetic field sensing element 602B is situated asymmetrically on the substrate 604 with respect to the fourth magnetic field sensing element 602D. For example, the second magnetic field sensing element 502B is separated from the axis of symmetry 610 by the first distance d1 in the first direction. The fourth magnetic field sensing element 602D is separated from the axis of symmetry 610 by the second distance d2 in the second direction. The second magnetic field sensing element 602B and the fourth magnetic field sensing element 602D may be configured to sense the same component of the magnetic field 608 (for example, the y-component). However, while the second magnetic field sensing element 602B and the fourth magnetic field sensing element 602D sense the same component of the magnetic field 608, as the second magnetic field sensing element 602B and the fourth magnetic field sensing element 602D are separated from the symmetry 610 by different distances, the second magnetic field sensing element 602B and the fourth magnetic field sensing element 602D sense non-equivalent values of the magnetic field 608.

While the first magnetic field sensing element 602A is the same distance d2 from the axis of symmetry 610 as the fourth magnetic field sensing element 602D, the first magnetic field sensing element 602A senses a different component of the magnetic field 608 than the fourth magnetic field sensing element 602D. As the first magnetic field sensing element 602A and the fourth magnetic field sensing element 602D sense different components of the magnetic field 608, the first magnetic field sensing element 602A and the fourth magnetic field sensing element 602D sense non-equivalent values of the magnetic field 608.

Additionally, while the third magnetic field sensing element 602C is the same distance d1 from the axis of symmetry 610 as the second magnetic field sensing element 602B, the third magnetic field sensing element 602C senses a different component of the magnetic field 608 than the second magnetic field sensing element 602B. As the second magnetic field sensing element 602B and the third magnetic field sensing element 602C sense different components of the magnetic field 608, the second magnetic field sensing element 602B and the third magnetic field sensing element 602C sense non-equivalent values of the magnetic field 608.

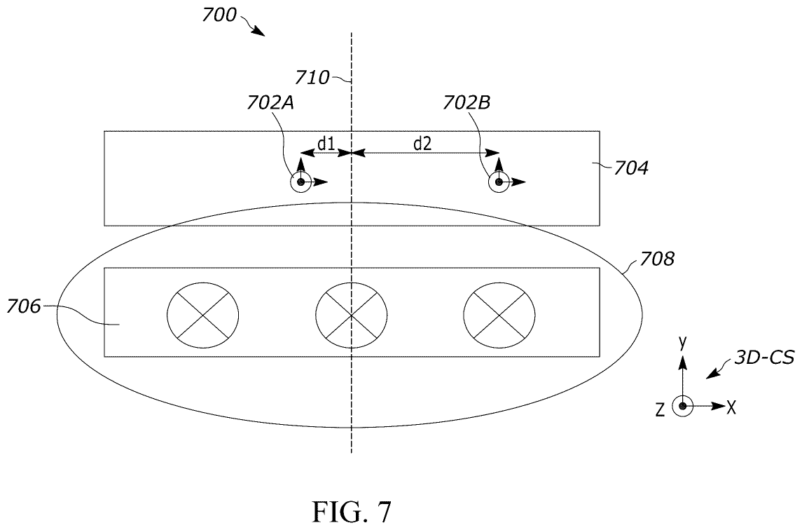

FIG. 7 is a cross-sectional view of another example coreless current sensor 700. The current sensor 700 includes a first magnetic field sensor 702A and a second magnetic field sensor 702B situated on a substrate 704 (for example, a printed circuit board). The substrate 704 is situated adjacent to a conductor 706. When current flows through the conductor 706, a magnetic field 708 is induced. At least a portion of the magnetic field 708 is sensed by the first magnetic field sensor 702A and the second magnetic field sensor 702B. While not illustrated, the current sensor 700 may also include a controller situated on the substrate 704.

In the example of FIG. 7, an axis of symmetry 710 intercepts a center of the substrate 704 and a center of the conductor 706. The first magnetic field sensor 702A and the second magnetic field sensor 702B are situated asymmetrically on the substrate 704 with respect to the axis of symmetry 710. For example, the first magnetic field sensor 702A is separated from the axis of symmetry 710 by a first distance d1 and in a first direction. The second magnetic field sensor 702B is separated from the axis of symmetry 710 by a second distance d2 in a second direction opposite the first direction.

The first magnetic field sensor 702A and the second magnetic field sensor 702B may be dual-axis sensors configured to sense at least two components of the magnetic field 708. For example, the first magnetic field sensor 702A and the second magnetic field sensor 702B may sense non-equivalent values in both the x-direction and the y-direction of the magnetic field 708. Accordingly, the first magnetic field sensor 702A and the second magnetic field sensor 702B may both include two or more magnetic field sensing elements integrated into a single sensor package. The magnetic field sensings elements of the first magnetic field sensor 702A may be at a same physical location but configured in different axial directions. Similarly, the magnetic field sensing elements of the second magnetic field sensor 702B may be at a same physical location but configured in different axial directions.

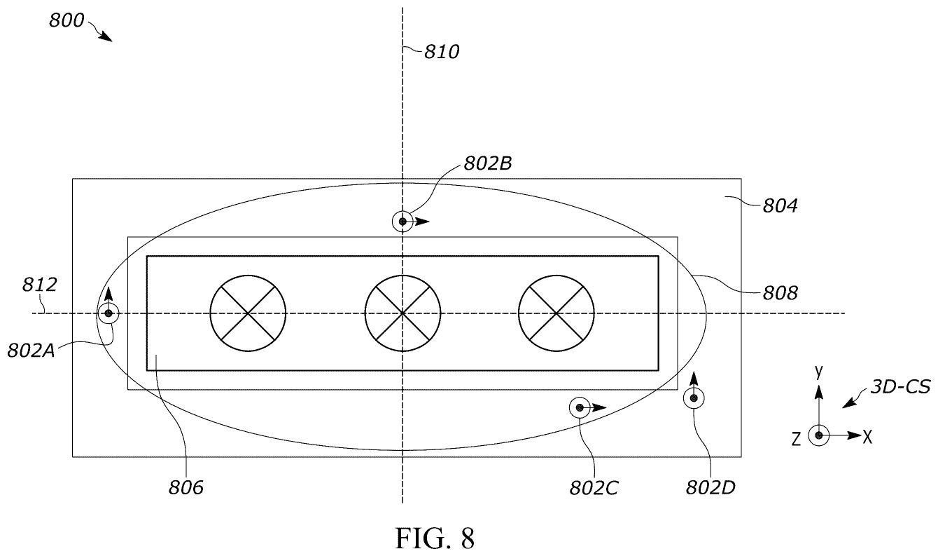

FIG. 8 is a cross-sectional view of another example coreless current sensor 800. The current sensor 800 includes a first magnetic field sensor 802A, a second magnetic field sensor 802B, a third magnetic field sensor 802C, and a fourth magnetic field sensor 802D situated on a substrate 804 (for example, a printed circuit board). The substrate 804 is situated adjacent to (for example, above or below) a conductor 806. When current flows through the conductor 806, a magnetic field 808 is induced. At least a portion of the magnetic field 808 is sensed by the first magnetic field sensor 802A, the second magnetic field sensor 802B, the third magnetic field sensor 802C, and the fourth magnetic field sensor 802D. While not illustrated, the current sensor 800 may also include a controller situated on the substrate 804.

In the example of FIG. 8, a first axis of symmetry 810 intercepts a center of the substrate 804 and a center of the conductor 806. A second axis of symmetry 812 also intercepts the center of the substrate 804 and the center of the conductor 806. The second axis of symmetry 812 is perpendicular to the first axis of symmetry 810. In some examples, the first axis of symmetry 810 and the second axis of symmetry 812 are on a same plane. The plane may be defined by, for example, the substrate 804. In the example of FIG. 8, the first axis of symmetry 810 is aligned with the y-direction of the three-dimensional coordinate system 3D-CS, and the second axis of symmetry 812 is aligned with the x-direction of the three-dimensional coordinate system 3D-CS.

The first magnetic field sensor 802A, the second magnetic field sensor 802B, the third magnetic field sensor 802C, and the fourth magnetic field sensor 802D are situated asymmetrically around the conductor 806. For example, the first magnetic field sensor 802A is situated on the second axis of symmetry 812 and is configured to sense a y-component of the magnetic field 808. The second magnetic field sensor 802B is situated on the first axis of symmetry 810 and is configured to sense an x-component of the magnetic field 808. The third magnetic field sensor 802C is offset from the first axis of symmetry 810 and the second axis of symmetry 812 and is configured to sense an x-direction of the magnetic field 808. The fourth magnetic field sensor 802D is offset from the first axis of symmetry 810 and the second axis of symmetry 812 and is configured to sense a y-direction of the magnetic field 808. The first magnetic field sensor 802A, the second magnetic field sensor 802B, the third magnetic field sensor 802C, and the fourth magnetic field sensor 802D may sense non-equivalent values relative to each other due to their various locations across the substrate 804.

Several examples of non-equivalent measurement information, such as non-equivalent values sensed by magnetic field sensing elements and magnetic field sensors, have been described herein. For example, magnetic field sensing elements at different positions on a substrate sense non-equivalent values of a magnetic field. Non-equivalent values may also refer to values sensed by two magnetic field sensing elements at substantially the same position on a substrate but configured to sense different components of a magnetic field.

In some instances, coreless current sensors described herein are calibrated prior to operation. For example, the coreless current sensors are calibrated prior to or during installation in a device. Calibration may be performed to obtain expected, or predicted, measurement values from magnetic field sensing elements.

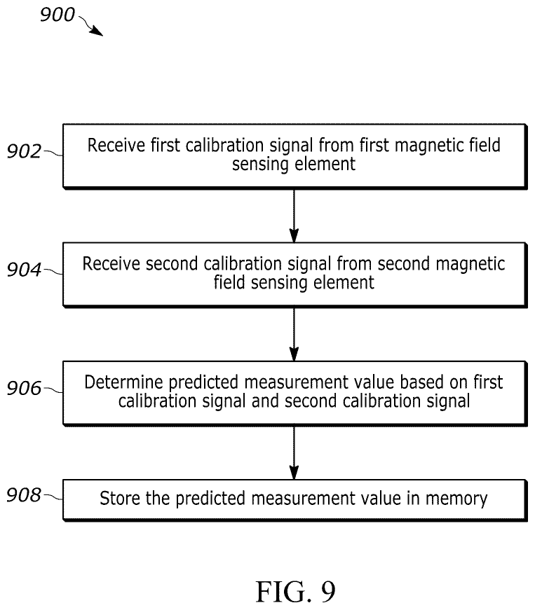

FIG. 9 illustrates an example method 900 of calibrating a coreless current sensor. The method 900 is described as being executed by the electronic processor 300. However, in some examples, the method 900 is performed by another external device connected to a current sensor, such as a computer. While the method 900 is described with respect to the current sensor 400 of FIG. 4, the method 900 may also be performed with respect to another coreless current sensor, such as the current sensor 500 of FIG. 5, the current sensor 600 of FIG. 6, the current sensor 700 of FIG. 7, or the current sensor 800 of FIG. 8. Additionally, while the process blocks illustrated in FIG. 9 provide one example of a method described herein, it is understood that some blocks may be removed, added, combined, reordered, or modified without departing from the spirit of the present disclosure.

At block 902, the electronic processor 300 receives a first calibration signal from the first magnetic field sensing element 402A. For example, a calibration current of known value is provided to the conductor 406. The calibration current causes a corresponding magnetic field 408 to be induced. The first magnetic field sensing element 402A senses the magnetic field 408. The first calibration signal may be defined according to Equation 1:

$${S}_{1}^{c a l} = {\sum }_{α = 1}^{{M}_{m}} {m}^{α} ( {x}_{1} ) \cdot {C}_{α}^{r e a l} \cdot {γ}^{c a l} \qquad Equation ( 1 )$$

### Where:

$${S}_{1}^{c a l}$$

is the magnetic field measurement output by the first magnetic field sensing element 402A during calibration;
m^{α}(x₁) is the multipole component of the magnetic field expansion at position x₁;
x₁ is the position of the first magnetic field sensing element 402A (for example, the first distance d1 from the axis of symmetry 410);

$${C}_{α}^{r e a l}$$

are coefficients of the multiple expansion; and
γ^{cal} is the value of the calibration current.

At block 904, the electronic processor 300 receives a second calibration signal from the second magnetic field sensing element 402B. For example, the second magnetic field sensing element 402B senses the magnetic field 408 caused by the calibration current through the conductor 406. The second calibration signal may be defined according to Equation 2:

$${S}_{2}^{c a l} = {\sum }_{α = 1}^{{M}_{m}} {m}^{α} ( {x}_{2} ) \cdot {C}_{α}^{r e a l} \cdot {γ}^{c a l} \qquad Equation ( 2 )$$

### Where:

$${S}_{2}^{c a l}$$

is the magnetic field measurement output by the second magnetic field sensing element 402B during calibration;
m^{α}(x₂) is the multipole component of the magnetic field expansion at position x₂;
Mₘ is a maximum multiple order used in the expansion; and
x₂ is the position of the second magnetic field sensing element 402B (for example, the second distance d2 from the axis of symmetry 410).

At block 906, the electronic processor 300 determines a predicted measurement value based on the first calibration signal and the second calibration signal. The predicted measurement value may include, for example, calibrations coefficients of the multipole expansion of the magnetic field 408. The calibration coefficients may be calculated by the electronic processor 300 according to Equation 3:

$${C}_{α}^{calibrated} = {\sum }_{k = 1}^{{N}_{s}} {M}_{α k} \cdot \frac{{S}_{k}^{c a l}}{{γ}^{c a l}} \qquad Equation ( 3 )$$

### Where:

$${C}_{α}^{calibrated}$$

is the calibrated coefficients;
   Nₛ is the number of magnetic field sensing elements;

$${M}_{α k} = {( {A}^{T} A )}^{- 1} {A}^{T} ; and$$

$$A = {m}^{α} ( {x}_{k} ) .$$

In some instances, to determine the predicted measurement value, the electronic processor 300 further calculates magnetic field prediction values using the calibrated coefficients. The magnetic field prediction values may be calculated for each magnetic field sensing element. For example, the magnetic field prediction values may be calculated by the electronic processor 300 according to Equation 4:

$${P}_{k} ( γ , t ) = {\sum }_{α = 1}^{{M}_{m}} {m}^{α} ( {X}_{k} + {t}^{estimated} ) \cdot {C}_{α}^{c a l i brated} \cdot {γ}^{estimated} \qquad Equation ( 4 )$$

### Where:

Pₖ(γ, t) is the magnetic field prediction value (e.g., the predicted measurement value) for a magnetic field sensing element k; and
t is a displacement vector indicating the estimated displacement of the magnetic field sensing element k from the nominal position at which it was calibrated.

At block 908, the electronic processor 300 stores the predicted measurement value in a memory. For example, the electronic processor 300 stores the magnetic field prediction values Pₖ(γ, t) in the memory 302. In another example, the electronic processor 300 stores the calibrated coefficients in the memory 302.

During operation, events such as mechanical vibrations or changes in temperature may cause a current sensor to shift from its original position. For example, the substrate 404 may shift with respect to the conductor 406, thereby also shifting the location of the first magnetic field sensing element 402A and the second magnetic field sensing element 402B. In such an instance, the stored predicted measurement values may be implemented by the electronic processor 300 to alter (e.g., correct) output current signals provided by the controller 204.

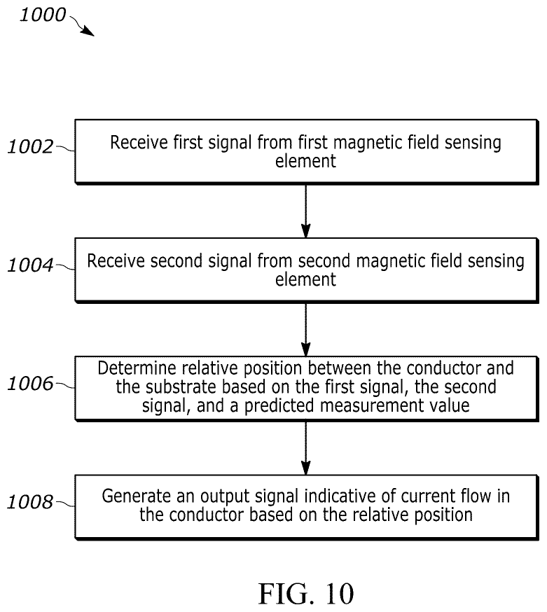

FIG. 10 illustrates an example method 1000 of operating a coreless current sensor. The method 1000 is described as being executed by the electronic processor 300. However, in some examples, the method 1000 is performed by another external device connected to a current sensor, such as a computer. While the method 1000 is described with respect to the current sensor 400 of FIG. 4, the method 1000 may also be performed with respect to another coreless current sensor, such as the current sensor 500 of FIG. 5, the current sensor 600 of FIG. 6, the current sensor 700 of FIG. 7, or the current sensor of FIG. 8. Additionally, while the process blocks illustrated in FIG. 10 provide one example of a method described herein, it is understood that some blocks may be removed, added, combined, reordered, or modified without departing from the spirit of the present disclosure.

At block 1002, the electronic processor 300 receives a first signal from the first magnetic field sensing element 402A. For example, the first magnetic field sensing element 402A provides a signal to the controller 204 indicative of the magnitude of the magnetic field 408 sensed by the first magnetic field sensing element 402A. The first signal may be defined according to Equation 5:

$${R}_{1} ( γ , t ) = {\sum }_{α = 1}^{{M}_{m}} {m}^{α} ( {x}_{1} + {t}^{r e a l} ) \cdot {C}_{a}^{r e a l} \cdot {γ}^{r e a l} \qquad Equation ( 5 )$$

### Where:

R₁(γ, t) is the first signal from the first magnetic field sensing element 402A.

At block 1004, the electronic processor 300 receives a second signal from the second magnetic field sensing element 402B. For example, the second magnetic field sensing element 402B provides a signal to the controller 204 indicative of the magnitude of the magnetic field 408 sensed by the second magnetic field sensing element 402B. The second signal may be defined according to Equation 6:

$${R}_{2} ( γ , t ) = {\sum }_{α = 1}^{{M}_{m}} {m}^{α} ( {x}_{2} + {t}^{r e a l} ) \cdot {C}_{α}^{r e a l} \cdot {γ}^{r e a l} \qquad Equation ( 6 )$$

### Where:

R₂(γ, t) is the second signal from the second magnetic field sensing element 402B.

At block 1006, the electronic processor 300 determines a relative position between the conductor 406 and the substrate 404 based on the first signal, the second signal, and a predicted measurement value. By way of example, the electronic processor 300 may determine a first difference between a first predictive value P₁(γ, t) and the first signal R₁(γ, t) from the first magnetic field sensing element 402A. The electronic processor 300 may also determine a second difference between the second predictive value P₂(γ, t) and the second signal R₂(γ, t) from the second magnetic field sensing element 402B. Thus, the relative position may be an estimated or calculated position of the substrate 404 compared to a position of the substrate 404 at the time of calibration of the current sensor 400.

In another example, the electronic processor 300 determines the relative position between the conductor 406 based on a quantity derived from the predicted measurement value. For example, the electronic processor 300 calculates the nonlinear least squares between the signals from the first magnetic field sensing element 402A and the second magnetic field sensing element 402B and their respective predictive values. For example, the electronic processor 300 calculates a nonlinear least squares NSL₁ between the first magnetic field sensing element 402A and a predicted measurement value associated with the first magnetic field sensing element 402A according to Equation 7:

$${NSL}_{1} = {‖ {R}_{1} - {P}_{1} ‖}_{min}^{2} \qquad Equation ( 7 )$$

The electronic processor 300 then calculates a nonlinear least squares NSL₂ between the second magnetic field sensing element 402B and a predicted measurement value associated with the second magnetic field sensing element 402B according to Equation 8:

$${NSL}_{2} = {‖ {R}_{2} - {P}_{2} ‖}_{min}^{2} \qquad Equation ( 8 )$$

To solve the nonlinear least squares NSL₁ and NSL₂, the electronic processor 300 may implement, for example, the Gauss-Newton algorithm or Kalman Filter algorithm, obtaining an estimated current value γ^{estimated} and an estimated displacement vector t^{estimated}.

At block 1008, the electronic processor 300 generates an output signal indicative of current flow in the conductor 406 based on the relative position. For example, the electronic processor 300 generates an output signal indicative of the current flow in the conductor 406 while accounting for shifts in the position of the substrate 404 (and, therefore, the first magnetic field sensing element 402A and the second magnetic field sensing element 402B). As one example, the electronic processor 300 may generate the output signal by applying the relative position as an offset value along one or more directions of greatest error contribution or error sensitivity of the current sensor 400. With reference to FIG. 1, should the current sensor 100 shift in the x-direction, the electronic processor 300 may apply the relative position as an offset value in the x-direction when generating the output signal.

In some instances, the electronic processor 300 maintains an estimated displacement of the current sensor 400 within the memory 302. For example, the electronic processor 300 stores the estimated displacement vector t^{estimated} within the memory 302. Each time the electronic processor 300 performs the method 1000, should the value of the estimated displacement vector t^{estimated} change, the electronic processor 300 updates the value of the estimated displacement vector t^{estimated} stored in the memory 302. The electronic processor 300 may update the value of the estimated displacement vector t^{estimated} stored in the memory 302 at a set interval (for example, once every second, once every minute, or the like).

In some instances, the electronic processor 300 calculates the estimated current value γ^{estimated} at a different rate than the electronic processor 300 calculates the estimated displacement vector t^{estimated}. For example, the electronic processor 300 may calculate the estimated current value γ^{estimated} more often (e.g., at a higher rate) than the estimated displacement vector t^{estimated}.

In some instances, other electrical components near current sensors described herein also generate a magnetic field in the form of a stray field. The stray field may interfere with the magnetic field induced by the conductor being measured by the current sensor, resulting in an offset in values sensed by the current sensor. In some examples described herein, the values of the plurality of magnetic field sensing elements 202 may be used by the controller 204 to filter out stray fields or compensate for offsets caused by stray fields.

Various aspects and implementations of the present disclosure may also be appreciated from the following enumerated example clauses, which are not claims, and which may represent systems, methods, and devices, all arranged in accordance with aspects of the present disclosure.
Clause 1. A current sensor for sensing current flow in a conductor, the current sensor comprising: a substrate; a first magnetic field sensing element mechanically connected to the substrate at a first measurement position; a second magnetic field sensing element mechanically connected to the substrate at a second measurement position; wherein the first magnetic field sensing element and the second magnetic field sensing element measure a magnetic field induced by current flow in the conductor in two non-equivalent measurement positions; and an electronic processor connected to the first magnetic field sensing element and the second magnetic field sensing element, the electronic processor configured to: receive a first signal from the first magnetic field sensing element, receive a second signal from the second magnetic field sensing element, determine a relative position between the conductor and the substrate based on the first signal, the second signal, and a predicted measurement value or a quantity derived from the predicted measurement value, and generate an output signal indicative of the current flow in the conductor based on the relative position.
Clause 2. The current sensor of clause 1, wherein the two non-equivalent measurement positions are at a same physical location but at different axial directions.
Clause 3. The current sensor of clause 1, wherein the two non-equivalent measurement positions are at a same distance from a center of the substrate but at different axial directions.
Clause 4. The current sensor of any one of clause 1 to clause 3, wherein first magnetic field sensing element and the second magnetic field sensing element are positioned asymmetrically with respect to each other along an axis of symmetry of the magnetic field.
Clause 5. The current sensor of any one of clause 1 to clause 4, wherein the first magnetic field sensing element and the second magnetic field sensing element are sensitive to a same magnetic field component of the magnetic field induced by the conductor.
Clause 6. The current sensor of any one of clause 1 to clause 5, wherein the first magnetic field sensing element and the second magnetic field sensing element are in a same plane.
Clause 7. The current sensor of any one of clause 1 to clause 6, wherein the first magnetic field sensing element and the second magnetic field sensing element are located at a different radial distance from the conductor.
Clause 8. The current sensor of any one of clause 1 to clause 7, further comprising: a third magnetic field sensing element mechanically connected to the substrate and configured to sense a magnetic field induced by current flow, wherein the third magnetic field sensing element is positioned at a third measurement position that provides measurement information that is non-equivalent to measurement information obtained at the first measurement position and non-equivalent to measurement information obtained at the second measurement position.
Clause 9. The current sensor of clause 8, wherein the second magnetic field sensing element and the third magnetic field sensing element are sensitive to different magnetic field components of the magnetic field induced by the conductor.
Clause 10. The current sensor of any one of clause 1 to clause 9, wherein the first magnetic field sensing element and the second magnetic field sensing element are integrated into a single sensor package.
Clause 11. The current sensor of any one of clause 1 to clause 10, wherein, to generate the output signal, the electronic processor is configured to: apply the relative position via an offset value along a single direction of greatest error contribution or error sensitivity.
Clause 12. The current sensor of any one of clause 1 to clause 11, wherein, while a calibration current is applied to the conductor thereby generating a calibration magnetic field and the electronic processor is further configured to or a second electronic processor is configured to: receive a first calibration signal from the first magnetic field sensing element indicative of the calibration magnetic field sensed by the first magnetic field sensing element, receive a second calibration signal from the second magnetic field sensing element indicative of the calibration magnetic field sensed by the second magnetic field sensing element, and determine the predicted measurement value based on the first calibration signal and the second calibration signal.
Clause 13. The current sensor of any one of clause 1 to clause 12, wherein the predicted measurement value includes a first predicted value associated with the first magnetic field sensing element and a second predicted value associated with the second magnetic field sensing element.
Clause 14. The current sensor of clause 13, wherein the electronic processor is configured to: determine a first difference between the first predicted value and the first signal; and determine a second difference between the second predicted value and the second signal to determine the relative position.
Clause 15. The current sensor of any one of clause 1 to clause 14, wherein the electronic processor is further configured to: update, at a set interval and using the relative position, a memory storing an estimated displacement of the current sensor along at least one component of the magnetic field.
Clause 16. A method for correcting an output signal of a current sensor, the method comprising: receiving a first signal from a first magnetic field sensing element; receiving a second signal from a second magnetic field sensing element, wherein the first magnetic field sensing element and the second magnetic field sensing element measure a magnetic field induced by current flow in a conductor in two non-equivalent measurement positions, and wherein the first magnetic field sensing element and the second magnetic field sensing element are each connected to a substrate; determining a relative position between the conductor and the substrate based on the first signal, the second signal, and a predicted measurement value or a quantity derived from the predicted measurement value; and generating an output signal indicative of the current flow in the conductor based on the relative position.
Clause 17. The method of clause 16, further comprising: applying the relative position via an offset value along a single direction of greatest error contribution or error sensitivity.
Clause 18. The method of any one of clause 16 to clause 17, wherein, while a calibration current is applied to the conductor thereby generating a calibration magnetic field, the method further includes: receiving a first calibration signal from the first magnetic field sensing element indicative of the calibration magnetic field sensed by the first magnetic field sensing element; receiving a second calibration signal from the second magnetic field sensing element indicative of the calibration magnetic field sensed by the second magnetic field sensing element; and determining the predicted measurement value based on the first calibration signal and the second calibration signal.
Clause 19. The method of any one of clause 16 to clause 18, wherein the predicted measurement value includes a first predicted value associated with the first magnetic field sensing element and a second predicted value associated with the second magnetic field sensing element.
Clause 20. The method of clause 19, further comprising: determining a first difference between the first predicted value and the first signal; and determining a second difference between the second predicted value and the second signal, to determine the relative position.
Clause 21. The method of any one of clause 16 to clause 20, further comprising: updating, at a set interval and using the relative position, a memory storing an estimated displacement of the current sensor along at least one component of the magnetic field.

In the foregoing specification, specific examples have been described. However, one of ordinary skill in the art appreciates that various modifications and changes may be made without departing from the scope of the arrangement as set forth in the claims below. Accordingly, the specification and figures are to be regarded in an illustrative rather than a restrictive sense, and all such modifications are intended to be included within the scope of present teachings.

Also, the illustrated components, unless explicitly described to the contrary, may be combined or divided into separate software, firmware and/or hardware. For example, instead of being located within and performed by a single electronic processor, logic and processing described herein may be distributed among multiple electronic processors. Similarly, one or more memory modules and communication channels or networks may be used even if arrangements described or illustrated herein have a single such device or element. Also, regardless of how they are combined or divided, hardware and software components may be located on the same computing device or may be distributed among multiple different devices. Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

The benefits, advantages, solutions to problems, and any element(s) that may cause any benefit, advantage, or solution to occur or become more pronounced are not to be construed as a critical, required, or essential features or elements of any or all the claims. The arrangement is defined solely by the appended claims including any amendments made during the pendency of this application and all equivalents of those claims as issued.

In addition, unless the context of their usage unambiguously indicates otherwise, the articles “a” and “an” should not be interpreted as meaning “one” or “only one.” Rather these articles should be interpreted as meaning “at least one” or “one or more”. Likewise, when the terms “the” or “said” are used to refer to a noun previously introduced by the indefinite article “a” or “an,” “the” and “said” mean “at least one” or “one or more” unless the usage unambiguously indicates otherwise.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it may be seen that various features are grouped together in various examples for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

We claim:

1. A current sensor for sensing current flow in a conductor, the current sensor comprising:
a substrate;
a first magnetic field sensing element mechanically connected to the substrate at a first measurement position;
a second magnetic field sensing element mechanically connected to the substrate at a second measurement position;
wherein the first magnetic field sensing element and the second magnetic field sensing element measure a magnetic field induced by current flow in the conductor in two non-equivalent measurement positions; and
an electronic processor connected to the first magnetic field sensing element and the second magnetic field sensing element, the electronic processor configured to:
receive a first signal from the first magnetic field sensing element,
receive a second signal from the second magnetic field sensing element,
determine a relative position between the conductor and the substrate based on the first signal, the second signal, and a predicted measurement value or a quantity derived from the predicted measurement value, and
generate an output signal indicative of the current flow in the conductor based on the relative position.

2. The current sensor of claim 1, wherein the two non-equivalent measurement positions are at a same physical location but at different axial directions.

3. The current sensor of claim 1, wherein first magnetic field sensing element and the second magnetic field sensing element are positioned asymmetrically with respect to each other along an axis of symmetry of the magnetic field.

4. The current sensor of claim 1, wherein the first magnetic field sensing element and the second magnetic field sensing element are sensitive to a same magnetic field component of the magnetic field induced by the conductor.

5. The current sensor of claim 1, wherein the first magnetic field sensing element and the second magnetic field sensing element are in a same plane.

6. The current sensor of claim 1, wherein the first magnetic field sensing element and the second magnetic field sensing element are located at a different radial distance from the conductor.

7. The current sensor of claim 1, further comprising:
a third magnetic field sensing element mechanically connected to the substrate and configured to sense a magnetic field induced by current flow, wherein the third magnetic field sensing element is positioned at a third measurement position that provides measurement information that is non-equivalent to measurement information obtained at the first measurement position and non-equivalent to measurement information obtained at the second measurement position.

8. The current sensor of claim 7, wherein the second magnetic field sensing element and the third magnetic field sensing element are sensitive to different magnetic field components of the magnetic field induced by the conductor.

9. The current sensor of claim 1, wherein the first magnetic field sensing element and the second magnetic field sensing element are integrated into a single sensor package.

10. The current sensor of claim 1, wherein, to generate the output signal, the electronic processor is configured to:
apply the relative position via an offset value along a single direction of greatest error contribution or error sensitivity.

11. The current sensor of claim 1, wherein, while a calibration current is applied to the conductor thereby generating a calibration magnetic field and the electronic processor is further configured to or a second electronic processor is configured to:
receive a first calibration signal from the first magnetic field sensing element indicative of the calibration magnetic field sensed by the first magnetic field sensing element,
receive a second calibration signal from the second magnetic field sensing element indicative of the calibration magnetic field sensed by the second magnetic field sensing element, and
determine the predicted measurement value based on the first calibration signal and the second calibration signal.

12. The current sensor of claim 1, wherein the predicted measurement value includes a first predicted value associated with the first magnetic field sensing element and a second predicted value associated with the second magnetic field sensing element.

13. The current sensor of claim 12, wherein the electronic processor is configured to:
determine a first difference between the first predicted value and the first signal; and
determine a second difference between the second predicted value and the second signal to determine the relative position.

14. The current sensor of claim 1, wherein the electronic processor is further configured to:
update, at a set interval and using the relative position, a memory storing an estimated displacement of the current sensor along at least one component of the magnetic field.

15. A method for correcting an output signal of a current sensor, the method comprising:
receiving a first signal from a first magnetic field sensing element;
receiving a second signal from a second magnetic field sensing element, wherein the first magnetic field sensing element and the second magnetic field sensing element measure a magnetic field induced by current flow in a conductor in two non-equivalent measurement positions, and wherein the first magnetic field sensing element and the second magnetic field sensing element are each connected to a substrate;
determining a relative position between the conductor and the substrate based on the first signal, the second signal, and a predicted measurement value or a quantity derived from the predicted measurement value; and
generating an output signal indicative of the current flow in the conductor based on the relative position.

16. The method of claim 15, further comprising:
applying the relative position via an offset value along a single direction of greatest error contribution or error sensitivity.

17. The method of claim 15, wherein, while a calibration current is applied to the conductor thereby generating a calibration magnetic field, the method further includes:
receiving a first calibration signal from the first magnetic field sensing element indicative of the calibration magnetic field sensed by the first magnetic field sensing element;
receiving a second calibration signal from the second magnetic field sensing element indicative of the calibration magnetic field sensed by the second magnetic field sensing element; and
determining the predicted measurement value based on the first calibration signal and the second calibration signal.

18. The method of claim 15, wherein the predicted measurement value includes a first predicted value associated with the first magnetic field sensing element and a second predicted value associated with the second magnetic field sensing element.

19. The method of claim 18, further comprising:
determining a first difference between the first predicted value and the first signal; and
determining a second difference between the second predicted value and the second signal, to determine the relative position.

20. The method of claim 15, further comprising:
updating, at a set interval and using the relative position, a memory storing an estimated displacement of the current sensor along at least one component of the magnetic field.
